(19) United States
(12) Patent Application Publication
(10) Pub. No.: US 2012/0161203 A1
(43) Pub. Date: Jun. 28, 2012

(54) Strain Enhancement in Transistors Comprising an Embedded Strain-Inducing Semiconductor Material by Alloy Species Condensation

(75) Inventors: Stefan Flachowsky, Dresden (DE); Stephan-Detlef Kronholz, Dresden (DE); Jan Hoentschel, Dresden (DE); Thilo Scheiper, Dresden (DE)

(73) Assignee: GLOBALFOUNDRIES INC., Grand Cayman (KY)

(21) Appl. No.: 13/196,318

(22) Filed: Aug. 2, 2011

(30) Foreign Application Priority Data
Dec. 28, 2010 (DE) 10 2010 064 290.8

(51) Int. Cl. H01L 21/336; H01L 21/225; H01L 29/78; B82Y 99/00; B82Y 40/00

(52) U.S. Cl. 257/192; 438/558; 438/197; 977/755; 257/E21.148; 257/E21.409; 257/E29.255

(57) ABSTRACT

In transistors requiring a high compressive strain, the germanium contents may be increased by applying a germanium condensation technique. In some illustrative embodiments, an oxidation process is performed in the presence of a silicon/germanium material obtained on the basis of selective epitaxial growth techniques, thereby increasingly oxidizing the silicon species, while driving the germanium into the lower lying areas of the active region, which finally results in an increased germanium concentration.

### BACKGROUND OF THE INVENTION

1. Field of the Invention

Generally, the present disclosure relates to the fabrication of highly sophisticated integrated circuits including advanced transistor elements that comprise strain-inducing semiconductor materials.

2. Description of the Related Art

The fabrication of advanced integrated circuits, such as CPUs, storage devices, ASICs (application specific integrated circuits) and the like, requires the formation of a large number of circuit elements on a given chip area according to a specified circuit layout. In a wide variety of circuits, field effect transistors represent one important type of circuit element that substantially determines performance of the integrated circuits. Generally, a plurality of process technologies are currently practiced for forming field effect transistors, wherein, for many types of complex circuitry, MOS technology is one of the most promising approaches due to the superior characteristics in view of operating speed and/or power consumption and/or cost efficiency. During the fabrication of complex integrated circuits using, for instance, MOS technology, millions of transistors, e.g., N-channel transistors and/or P-channel transistors, are formed on a substrate including a crystalline semiconductor layer. A field effect transistor, irrespective of whether an N-channel transistor or a P-channel transistor is considered, typically comprises so-called PN junctions that are formed by an interface of highly doped regions, referred to as drain and source regions, with a slightly doped region, such as a channel region, disposed adjacent to the highly doped regions. In a field effect transistor, the conductivity of the channel region, i.e., the drive current capability of the conductive channel, is controlled by a gate electrode formed adjacent to the channel region and separated therefrom by a thin insulating layer. The conductivity of the channel region, upon formation of a conductive channel due to the application of an appropriate control voltage to the gate electrode, depends on the dopant concentration, the mobility of the charge carriers and, for a given extension of the channel region in the transistor width direction, on the distance between the source and drain regions, which is also referred to as channel length. Hence, the conductivity of the channel region substantially affects the performance of MOS transistors. Thus, as the speed of creating the channel, which depends on the conductivity of the gate electrode, and the channel resistivity substantially determine the transistor characteristics, the scaling of the channel length, and associated therewith the reduction of channel resistivity, which in turn causes an increase of gate resistivity due to the reduced dimensions, is a dominant design criterion for accomplishing an increase in the operating speed of the integrated circuits.

Since many of the most recent developments for reducing the channel length are associated with significant challenges, for instance using sophisticated gate electrode structures by using high-k dielectric materials and metal-containing gate electrode materials, other approaches have been developed in order to enhance transistor performance for a given gate length and a thickness of a gate dielectric material. For example, by creating a certain strain component in the channel region of the transistor elements, the charge carrier mobility and, thus, the overall conductivity of the channel may be enhanced. For a silicon material having a standard crystallographic configuration, i.e., a (100) surface orientation with the channel length direction oriented along a <110> equivalent direction, the creation of a tensile strain component in the current flow direction, may enhance conductivity of electrons, thereby improving transistor performance of N-channel transistors. On the other hand, generating a compressive strain component in the current flow direction may increase hole mobility and thus provide superior conductivity in P-channel transistors. Consequently, a plurality of strain-inducing mechanisms have been developed in the past which may per se require a complex manufacturing sequence for implementing the various strain-inducing techniques. For example, one promising approach that is frequently applied is the incorporation of a compressive strain-inducing silicon/germanium alloy in the drain and source areas of P-channel transistors. For this purpose, in an early manufacturing stage, cavities are selectively formed adjacent to the gate electrode structure of the P-channel transistor, while the N-channel transistors are covered by a spacer layer. Additionally, the gate electrode of the P-channel transistor has to be encapsulated in order to not unduly expose the gate electrode material to the etch ambient for forming the cavities and also for providing an efficient growth mask during the selective epitaxial growth process, in which the silicon/germanium alloy may be grown on a crystalline substrate material, while a significant deposition of the alloy on dielectric surface areas may be suppressed by appropriately selecting the corresponding process parameters.

A strain-inducing mechanism as described above is a very efficient concept for improving the transistor performance, at least for P-channel transistors, since, for a given gate length, an increased current drive capability may be achieved. The finally obtained strain component in the channel region significantly depends on the internal strain level of the silicon/germanium material, which in turn strongly depends on the lattice mismatch between the silicon/germanium alloy, i.e., its natural lattice constant, and the remaining template material of the silicon-based active region. Frequently, a desired increase of the germanium concentration in view of increasing the lattice mismatch may be associated with significant technological problems in view of germanium agglomeration and the creation of significant lattice defects so that germanium concentration levels of above 30 atomic percent are difficult to achieve on the basis of presently available selective epitaxial growth techniques.

In addition to the germanium concentration, also the effective offset of the strained silicon/germanium alloy from the channel region strongly influences the finally achieved strain level in the channel region. Therefore, great efforts are being made in implementing process techniques in which a reduced offset and/or an appropriate shape of the cavities can be achieved in order to obtain a desired high strain level upon epitaxially growing the silicon/germanium alloy.

FIG. 1a schematically illustrates a cross-sectional view of a complex semiconductor device 100 in which a transistor 150 is provided on the basis of an embedded silicon/germanium alloy in order to obtain superior strain conditions. As illustrated, the semiconductor device 100 comprises a substrate 101, such as a silicon material and the like, above which is formed a silicon layer 103, wherein, in the example shown, a silicon-on-insulator (SOI) architecture is used, in which a buried insulating material 102 is formed between a crystalline material of the substrate 101 and the actual active silicon layer 103. Typically, the silicon layer 103 is laterally separated into a plurality of active regions 103A, which are to be understood as silicon regions in and above which one or more transistor elements, such as the transistor 150, are to be provided. For convenience, in FIG. 1a, a single active region 103A is illustrated, which is typically laterally delineated by an isolation region 1031, such as a shallow trench isolation and the like. The transistor 150, which is to represent a P-channel transistor, comprises a gate electrode structure 155, which in turn includes a gate dielectric material 155B that separates an electrode material 155A from a portion of the active region 103A, such as a channel region 151. Furthermore, the gate electrode structure comprises a spacer structure 155S having any appropriate configuration. It should be appreciated that the gate electrode structure 155 has any appropriate basic configuration as required for the type of transistor under consideration. For example, in sophisticated applications, a length of the gate electrode structure 155, i.e., in FIG. 1a, the horizontal extension of the electrode material 155A, may be 50 nm and significantly less. It should be appreciated that a transistor length direction is a direction perpendicular to the drawing plane of FIG. 1a. Moreover, the gate electrode structure 155 may comprise any desired materials, such as high-k dielectric materials, which are to be understood as dielectric materials having a dielectric constant of 10.0 and higher, which may thus ensure a required capacitive coupling of the electrode material 155A to the channel region 151, while at the same time keeping any gate leakage currents at an acceptable level. Similarly, the electrode material 155A may represent any appropriate material system, for instance a polysilicon material, possibly in combination with metal-containing materials, for instance in the form of titanium nitride and the like, as is frequently used in highly complex gate electrode structures formed on the basis of a high-k dielectric material. Moreover, the transistor 150 comprises an embedded silicon/germanium alloy 152 which, as previously discussed, is formed on and within a base material 103B of the active region 103A, thereby resulting in a strained state, which in turn induces a desired compressive strain component 152S within the channel region 151. Consequently, the charge carrier mobility, in the present case the whole mobility, in the channel region 151 may be efficiently increased due to the presence of the strain 152S. Furthermore, drain and source regions 153, for instance provided in the form of implantation regions, possibly in combination with highly doped areas within the silicon/germanium material 152, which may have been formed during the selective deposition of the material 152, are provided and have any desired lateral and vertical profile in order to comply with the performance requirements of the device 150. In sophisticated applications, the drain and source regions 153 may extend down to an interface 102S that is formed between the buried insulating layer 102 and the base silicon material 103B. The thickness or depth of the active region 103A, at least in the area of the channel region 151, may be 100 nm and less, for instance approximately 70 nm, depending on the overall transistor requirements.

The semiconductor device 100 as illustrated in FIG. 1a may be formed on the basis of the following process techniques. The plurality of active regions in the semiconductor layer 103, such as the active region 103A, may be delineated in a lateral direction by applying corresponding manufacturing techniques for forming the isolation structure 1031. To this end, well-established and sophisticated lithography, etch, deposition and planarization processes are applied. After or prior to forming the isolation structure 1031, any required dopant species may be incorporated into the active region 103A, for instance for defining the basic conductivity type and other basic transistor characteristics of the transistor 150. Next, a material layer stack is formed in accordance with any process and device requirements for providing the gate electrode structure 155. For example, silicon dioxide-based dielectric materials may be grown on the active region 103A, followed by an appropriate electrode material, such as polysilicon and the like, if a complex gate electrode structure is to be provided on the basis of conventional dielectric materials, such as silicon oxynitride in combination with a polysilicon electrode material. In other cases, in addition to a very thin silicon oxide-based material, a high-k dielectric material may be provided, for instance in combination with a metal-containing electrode material, such as titanium nitride and the like, if a high-k metal gate electrode structure is to be implemented. In still other cases, any such highly sophisticated gate electrode configurations may be implemented in a very advanced manufacturing stage, for instance upon removing at least a portion of the gate electrode structure 155 in a very late manufacturing stage. Thereafter, complex lithography and patterning strategies are applied in order to form the gate electrode material 155A and the gate dielectric material 155B so as to have the desired cross-sectional shape and so as to correspond to the target critical dimensions. Next, the gate electrode material 155A may be appropriately encapsulated, for instance on the basis of a cap material (not shown), which may also be used for patterning the electrode material 155A and in combination with a sidewall spacer structure (not shown) in order to form cavities in the active region 103A, the size and shape of which may be thus defined by a corresponding etch strategy and the configuration of the gate electrode structure 155 including the encapsulation at this manufacturing stage. For example, frequently, a substantially anisotropic etch technique is applied, for instance based on well-established plasma assisted etch recipes, thereby removing a portion of the active region while still preserving the portion 103B of the silicon base material. Thereafter, appropriate surface preparation processes are applied in order to prepare any exposed crystalline surface areas for the subsequent selective epitaxial growth of the silicon/germanium alloy 152. To this end, a plurality of well-established selective epitaxial growth techniques are available, wherein, however, as discussed above, process parameters have to be selected so that a significant material deposition is restricted to crystalline semiconductor surface areas, such as to surface areas of the exposed base material 103B, while a pronounced material deposition on any dielectric surface areas is suppressed. It turns out that presently available deposition recipes suffer from pronounced material irregularities when it is attempted to increase the contents of the germanium species above approximately 30 atomic percent in the material 152, which may thus result in a significant deterioration of the overall transistor characteristics. Consequently, although a high germanium concentration and thus a highly strained state of the material 152 would be highly desirable in view of increasing the strain component 152S, the limitations of the selective epitaxial growth process may not allow a corresponding increase of the germanium concentration. Similarly, in view of integrity of, for instance, the gate dielectric material 155B, the lateral offset of the material 152 with respect to the channel region 151 may not be arbitrarily reduced since, in this case, a high probability exists in exposing any edge areas of the gate dielectric material 155B to any reactive process atmospheres which may thus result in pronounced fluctuations of device characteristics, in particular when sophisticated high-k dielectric materials are used in the gate electrode structure 155.

After the selective deposition of the silicon/germanium alloy 152, the further processing is typically continued by forming the drain and source regions 153, which is frequently accomplished by appropriate implantation techniques in combination with an appropriate masking regime, followed by anneal processes in which the final desired profile of the drain and source regions 153 is adjusted.

Consequently, the resulting strain 152S in the channel region 151 strongly depends on the germanium concentration in the material 152 and its extension in the depth direction, as indicated as 152D, while also the lateral distance with respect to the channel region 151 has a significant influence on the finally achieved performance of the transistor 150.

FIG. 1b schematically illustrates the measurement results of the atomic concentration in the active region along the depth direction, as is indicated as direction D in FIG. 1a. To this end, any well-established measurement technique may be applied, for instance, secondary ion mass spectroscopy (SIMS) and the like. In the graph of FIG. 1b, the horizontal axis represents the extension along the depth direction in nanometers, while the vertical axis illustrates the atomic concentration of the semiconductor materials. It should be appreciated that any very small concentrations of dopant atoms and the like are not illustrated in FIG. 1b. Thus, as shown, at a depth that substantially corresponds to the surface, as indicated by depth 0, a germanium concentration of approximately 21 percent is obtained so that the corresponding silicon concentration is approximately 79 percent. These concentration values are substantially constant with increasing depth, which illustrates that, during the selective epitaxial growth process for forming the material 152, a substantially constant germanium concentration has been incorporated. It should be appreciated, however, that, in other process recipes, a varying germanium concentration may be incorporated if considered appropriate for the performance of the transistor 150 of FIG. 1a. At a depth of approximately 45 nm, the germanium concentration rapidly drops, while accordingly the silicon concentration increases to approximately 100 percent, which thus represents the configuration of the silicon base material 103, which may then further extend to a depth of approximately 70 nm, when the buried insulating material is provided, as for instance explained above with reference to FIG. 1a. Consequently, a further gain in performance of the transistor 150 of FIG. 1a would require an increase of the germanium concentration which, however, is accompanied by significant lattice defects and the like, thereby making this approach less attractive. On the other hand, a further improvement may require a reduced lateral offset of the material 152, which is also associated with significant process irregularities, thereby contributing to significant fluctuations in transistor characteristics.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure provides manufacturing techniques and semiconductor devices in which a semiconductor material of significantly increased internal strain may be incorporated into the drain and source areas of transistors in which a highly compressive strain component is considered advantageous for adjusting the overall transistor characteristics. To this end, the germanium concentration in a semiconductor base material, such as a silicon material, a silicon/germanium material and the like, may be increased by applying a germanium condensation process in which specific areas in the active region may be enriched with the germanium species in a highly controllable manner, thereby achieving germanium concentrations that may be above 30 atomic percent, if desired. Furthermore, the vertical extension of the germanium species may be increased and, if desired, also a lateral extension of the germanium concentration may be adjusted on the basis of the germanium condensation process.

One illustrative method disclosed herein comprises forming a semiconductor material on a silicon-containing semiconductor base material of a semiconductor region that has formed thereon a gate electrode structure, wherein the semiconductor material comprises germanium. The method further comprises oxidizing at least a portion of the semiconductor material so as to drive a germanium species into the silicon-containing semiconductor base material. Furthermore, an oxidized portion of the semiconductor material is removed and drain and source regions are formed in the semiconductor region.

A further illustrative method disclosed herein relates to forming a transistor. The method comprises forming a silicon/germanium alloy in a silicon-containing semiconductor base material of an active region of the transistor. Furthermore, the method comprises annealing the silicon/germanium alloy so as to convert silicon into a silicon compound in at least a portion of the silicon/germanium alloy and to increase a germanium concentration outside of the silicon compound. The method further comprises removing the silicon compound and forming drain and source regions in the active region, wherein the drain and source regions have a strained state caused by the increased germanium concentration.

One illustrative semiconductor device disclosed herein comprises a gate electrode structure of a transistor formed above an active region. The semiconductor device further comprises a silicon-containing channel region that is formed in the active region under a portion of the gate electrode structure. Moreover, a strained semiconductor material is formed in the active region and induces a compressive strain in the channel region, wherein the strained semiconductor material comprises germanium with a maximum concentration of 30 atomic percent or higher. The semiconductor device further comprises drain and source regions that are formed in the active region. Additionally, the semiconductor device comprises a buried insulating layer that is formed below the active region and forms an interface therewith, wherein the strained semiconductor material comprises germanium extending to the interface in the drain and source regions.

### BRIEF DESCRIPTION OF THE DRAWINGS

The disclosure may be understood by reference to the following description taken in conjunction with the accompanying drawings, in which like reference numerals identify like elements, and in which:

FIG. 1a schematically illustrates a cross-sectional view of a semiconductor device comprising a P-channel transistor in which a strain-inducing silicon/germanium alloy is formed on the basis of conventional process techniques;

FIG. 1b schematically illustrates measurement results of the material composition in the active region, wherein a germanium concentration of 30 atomic percent or less is provided in accordance with currently available selective epitaxial growth techniques;

FIGS. 2a-2b schematically illustrate cross-sectional views of a semiconductor device including a transistor in which a strain-inducing embedded semiconductor material based on germanium is formed by using a germanium condensation process, according to illustrative embodiments;

FIGS. 2c-2d schematically illustrate measurement results of the material composition in the active region obtained on the basis of the manufacturing techniques described in

FIGS. 2a-2b, wherein a maximum germanium concentration of approximately 20 atomic percent and higher may be obtained, while the germanium may extend down to a buried insulating material, according to illustrative embodiments;

FIGS. 2e-2f schematically illustrate a cross-sectional view of the semiconductor device according to still further illustrative embodiments in which a germanium species may be incorporated into a semiconductor base material without providing a germanium-containing alloy in the active region, according to further illustrative embodiments; and

FIG. 2g schematically illustrates a cross-sectional view of a transistor comprising an embedded germanium-comprising semiconductor material for obtaining superior strain conditions, according to still further illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present disclosure provides manufacturing techniques and semiconductor devices in which the germanium concentration in a semiconductor base material, such as a silicon material, a silicon/germanium material and the like, may be increased by applying a germanium condensation process in which the germanium atoms are driven into the lower lying base material, however, without significantly increasing any lattice defects. Consequently, in this manner, the base material is enriched by the germanium species, wherein increasingly atoms of the base material, such as silicon atoms, are replaced at lattice sites by the germanium species so as to obtain, in total, a maximum germanium concentration that is higher compared to a germanium concentration of the initial semiconductor base material. The germanium condensation may be effected by, for instance, in some illustrative embodiments, performing an oxidation process, for instance in the presence of a substantially pure oxygen atmosphere and the like at elevated temperatures of approximately 900° C. and higher, wherein the difference in chemical activation energies between silicon and germanium results in the formation of preferably a silicon dioxide material, while the germanium species is driven into the lower-lying base material. Consequently, based on the characteristics of the oxidation process and the configuration of the initial semiconductor materials, i.e., the semiconductor base material and a germanium-containing semiconductor material formed thereabove, a highly controllable germanium enrichment of the semiconductor base material may be accomplished, which may thus result in significantly higher germanium concentrations compared to conventional selective epitaxial growth techniques, as is also described above. Since the reaction behavior of the germanium condensation process may be readily determined in advance, for instance by performing experiments with different parameter settings, for instance in terms of anneal temperature, oxygen contents, process time and the like, the resulting germanium concentration profile in the active region may be adjusted with high precision, thereby enabling a dedicated adaptation of the transistor characteristics since, as previously discussed, the strain conditions represent a very efficient mechanism for enhancing and controlling the transistor characteristics in devices in which highly controlled strain conditions are required. For example, in P-channel transistors, a very high compressive strain is extremely advantageous for enhancing hole mobility and thus switching speed and current drive capability, as discussed above. In other cases, germanium may be incorporated in a highly controlled manner into any type of semiconductor base material in order to specifically determine the strain conditions therein. To this end, also tensile-strained base materials may be treated if a precisely controlled reduction of the tensile strain is desired. It, thus, should be appreciated that, in many illustrative embodiments disclosed herein, the germanium condensation mechanism may be advantageously applied to P-channel transistors in order to increase the compressive strain compared to conventional strategies, while, in other illustrative embodiments, the highly controlled germanium incorporation may also be advantageously used for adjusting other transistor characteristics, such as the final magnitude of a tensile strain, electronic characteristics and the like.

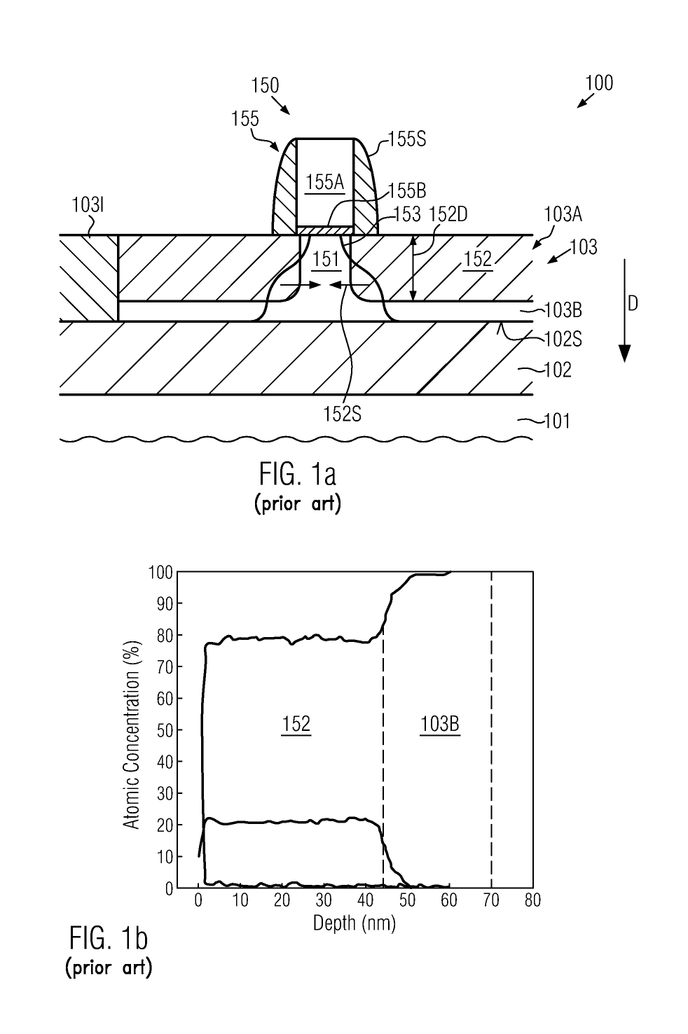

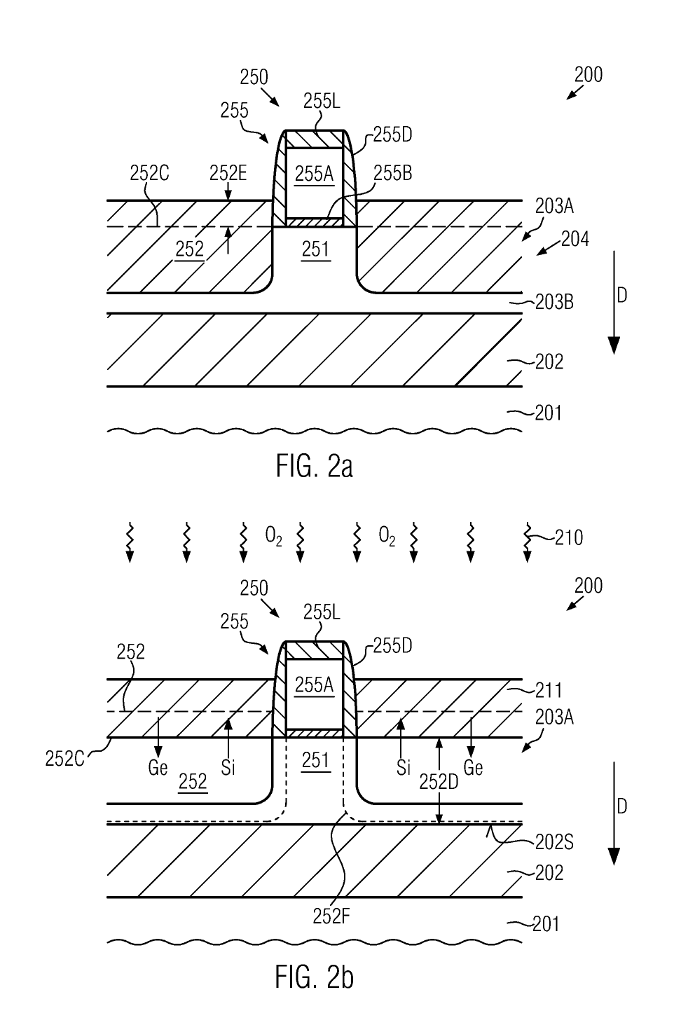

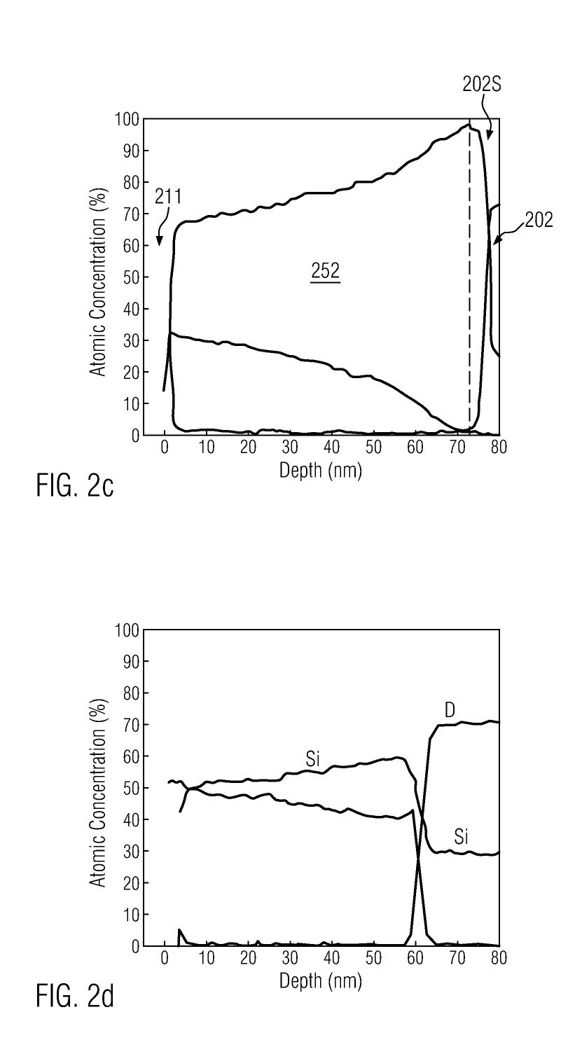

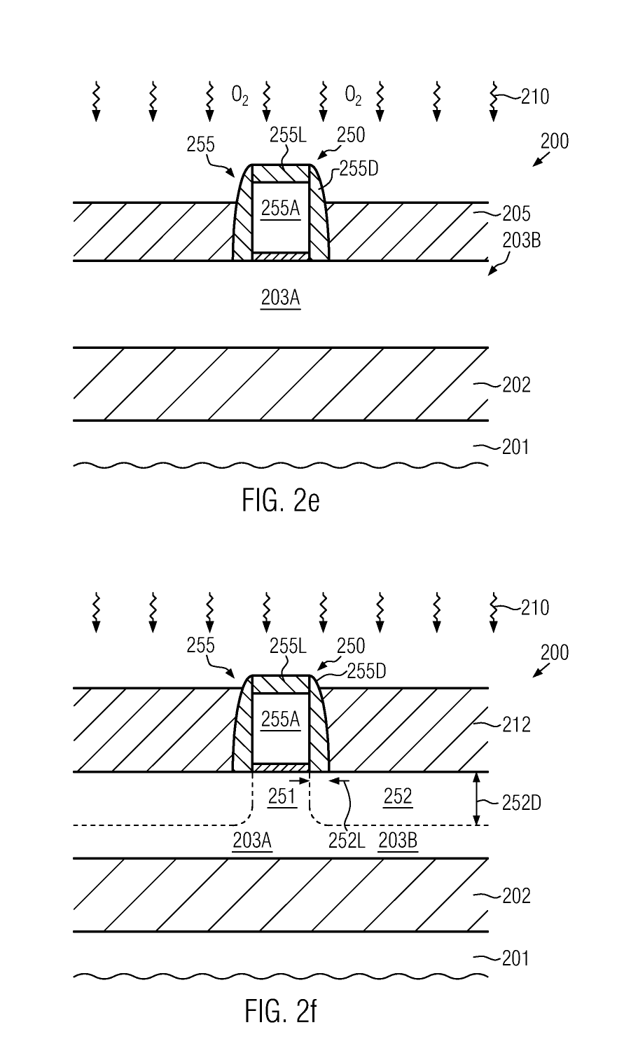

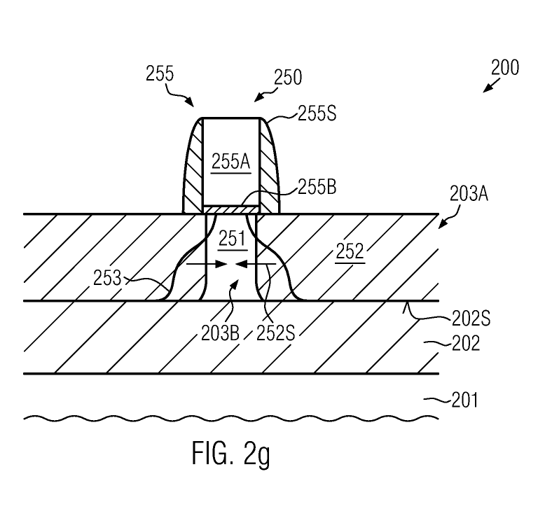

With reference to FIGS. 2a-2g, further illustrative embodiments will now be described in more detail, wherein reference may also be made to FIGS. 1a-1b, if appropriate.

FIG. 2a schematically illustrates a cross-sectional view of a semiconductor device 200, which may comprise a transistor 250 which requires an embedded germanium species for adjusting the overall transistor characteristics, such as the strain conditions in a channel region, as is also previously discussed. As illustrated, the semiconductor device 200 may comprise a substrate 201, in which may be provided a plurality of active regions, which are to be understood as any appropriate semiconductor regions in and above which one or more transistor elements, such as a transistor 250, are to be formed. For convenience, in FIG. 2a, a single active region 203A is illustrated, which may typically be delineated in the lateral directions by an appropriate isolation structure, such as a shallow trench isolation, as is also previously explained with reference to the semiconductor device 100 of FIG. 1a. It should be appreciated that the active region 203A may, at an initial manufacturing stage, represent a more or less homogeneous semiconductor material, such as a silicon material and the like, which may also be referred to as a semiconductor base material, wherein, in FIG. 2a, a portion thereof, indicated as 203B, may still be present. In some illustrative embodiments, as for instance shown in FIG. 2a, a buried insulating layer 202 may be formed between the substrate 201 and the active region 203A, thereby forming an SOI configuration. The buried insulating layer 202 may, for instance, be comprised of silicon dioxide, silicon nitride and the like. In other illustrative embodiments (not shown), the active region 203A may be formed in a crystalline semiconductor material, which may be directly formed on a crystalline material of the substrate 201, which may thus represent a bulk configuration. It should further be appreciated that the buried insulating layer 202 may not necessarily extend across the entire substrate 201 but may, in some illustrative embodiments, be locally provided in some certain device areas of the device 200. Moreover, in the manufacturing stage shown, the transistor 250 may comprise a gate electrode structure 255, which in turn may include a gate dielectric material 255B that separates an electrode material 255A from a portion of the active region 203A, which may also be referred to as a channel region 251, wherein it should be appreciated that the final lateral extension of the channel region 251 has to be defined on the basis of source and drain regions still to be formed. The gate dielectric material 255B may comprise well-established conventional dielectric materials, such as silicon dioxide, silicon oxynitride and the like, while, in other cases, in addition to or alternatively to these conventional dielectrics, high-k dielectric materials may be used, for instance in the form of any appropriate metal oxides and the like. Similarly, the electrode material 255A may be provided in the form of a polysilicon material, a silicon/germanium material or as a combination of a metal-containing electrode material and a semiconductor material, depending on the overall device requirements. Furthermore, as also discussed above, the gate electrode structure 255 may be formed on the basis of sophisticated design rules in which a gate length of 50 nm and significantly less may have to be implemented. In the manufacturing stage shown, the gate electrode structure 255 may comprise a cap material 255L, for instance in the form of silicon dioxide, silicon nitride and the like, in combination with a spacer structure 255D, thereby confining the materials 255B, 255A. A reliable confinement of the materials 255B and 255A, or at least a portion thereof, may be particularly important when considering highly complex high-k metal gate electrode structures, in which the sensitive high-k dielectric materials in combination with a metal-containing electrode material are provided in an early manufacturing stage.

Moreover, in the manufacturing stage shown, a silicon/germanium alloy 252 is formed in cavities 204 which are provided in the base material 203B while, as indicated by the dashed line 252C, the material 252 may be provided with a desired extra height so as to extend above the channel region 251, i.e., above the interface formed by the channel region 251 and the gate dielectric layer 255B.

The semiconductor device 200 as shown in FIG. 2a may be formed on the basis of any appropriate process technique. For example, the active region 203A may be formed on the basis of process techniques as are also described above with reference to the device 100. Thereafter, the gate electrode structure 255 may be provided including any appropriate process technique, as for instance described with respect to the device 100, that is, an appropriate material layer stack, for instance including the cap material 255L, is provided on the basis of appropriate deposition techniques followed by sophisticated lithography and etch processes for patterning the electrode material 255A in combination with the material 255B. During the patterning process the, cap material 255L may act as a hard mask material and the like. Thereafter, the spacer structure 255D may be formed, for instance, by depositing a silicon nitride material and the like, and patterning the same so as to obtain the spacer structure 255D. Thereafter, any appropriate etch technique may be applied so as to form the cavities 204 having a desired depth and shape, as is also previously discussed. For example, a substantially anisotropic etch recipe may be applied, while in other cases any other process techniques, such as isotropic etch steps, may be implemented, at least at a certain phase of the etch process, if considered appropriate. In other cases, crystallographically anisotropic etch processes may be applied so as to use specific crystal planes as efficient etch stop layers, thereby providing superior uniformity in defining the size and shape of the cavities 204. Next, a selective epitaxial growth process may be applied in which process parameters are adjusted such that a desired germanium concentration may be obtained without inducing pronounced lattice defects. For example, the material 252 may be formed on the basis of well-established process recipes with a germanium concentration of approximately 20-30 atomic percent. It should be appreciated, however, that the germanium concentration may be varied during the deposition process, if considered appropriate. Moreover, a certain amount of extra height, as indicated by 252E, may be provided, wherein also in this case the same or a different germanium concentration may be used. In the example shown, the extra height 252E may be selected such that this material may be consumed during a subsequent germanium condensation process so as to obtain a final height of the material 252, which may substantially correspond to the initial height of the base material 203B, while in other cases any other geometric configurations may be implemented. For example, if a generally recessed drain and source configuration for the material 252 is considered appropriate for the overall performance of the transistor 250, the extra height 252E may be appropriately selected so as to result in a further consumption of material within the cavities 204. On the other hand, if a raised configuration of the material 252 after the germanium condensation process is considered appropriate, the extra height 252E is selected so as to preserve a portion of the material 252 above the height level defined by the channel region 251.

Consequently, in this manufacturing stage, the active region 203A may have a germanium concentration along the depth direction D that varies within the material 252 in accordance with the selected deposition parameters, while a significant drop of the germanium concentration at the interface between the base material 203B and the material 252 may be observed, as for instance shown in FIG. 1b for the conventional regions 152 and 103B.

FIG. 2b schematically illustrates the semiconductor device 200 during a germanium condensation process 210, which, in the embodiment shown, is applied in the form of an oxidation process. For example, the process 210 may be established in a substantially pure oxygen atmosphere, as is also typically applied when forming silicon dioxide materials in a highly controllable manner. For example, the substrate temperature and thus the process temperature may be adjusted to approximately 900° C. and higher, such as 1000° C. and higher, with a substantially pure oxygen atmosphere in which an oxidation rate may be one to several nanometers per minute. Consequently, during a certain process time, for instance in the range of 40-80 minutes and higher, a corresponding portion of the material 252 may be increasingly converted into a silicon dioxide layer, as indicated by 211. As is well known, upon oxidizing a silicon-based material, a certain thickness of the semiconductor material may be consumed while additionally an increase of volume may occur since typically silicon dioxide material has a greater volume compared to a silicon material. Consequently, during the process 210, a portion of the material 252 may be consumed, starting from its initial height, indicated by 252, thereby forming the oxide layer 211 which may thus expand into the depth and may also grow into the height direction. Thus, at the end of the process 210, the layer 211 may have its final thickness, which in the embodiment shown is selected so as to substantially extend to an initial height level, as indicated by 252C, when a substantially planar configuration of the remaining material 252 is desired. It should be appreciated, as discussed above with reference to FIG. 2a, that any other configuration may be implemented upon controlling the parameters of the process 210 and/or controlling the parameters of the material 252 in its initial state, as shown in FIG. 2a, for instance with respect to its extra height 252E and the like. As already explained above, silicon and germanium may have different chemical activation energies so that preferably the silicon species reacts with the oxygen in the atmosphere of the process 210, thereby forming silicon oxide material of the layer 211, while on the other hand the germanium species is driven into any lower lying areas, thereby increasingly enriching these lower lying areas with the germanium species. Consequently, the initial germanium concentration in these lower lying areas may thus be increased, thereby obtaining a maximum germanium concentration in the remaining material 252 that is higher than the initial germanium concentration obtained by the selective epitaxial growth process. Moreover, the germanium species may be driven into the base material 203B (FIG. 2a) and may also extend in the lateral direction, as indicated by 252F in FIG. 2b. Therefore, in some illustrative embodiments, the germanium species may extend down to an interface 202S formed between the buried insulating material 202, which may act as a diffusion barrier, and the material 252. It should be appreciated that the germanium concentration at the interface 202S may be adjusted on the basis of the process parameters of the process 210 and the configuration of the initial material 252, wherein appropriate material compositions and process parameters may be readily determined on the basis of experiments. In this respect, it is to be noted that the composition of the initial material 252 as well as the process conditions of the process 210 may be controlled with high precision so that the finally obtained germanium concentration and profile in the region 252 may also be adjusted with a high degree of accuracy, thereby not unduly contributing to any transistor variabilities.

FIG. 2c schematically illustrates respective measurement results obtained from a structure that corresponds to the device as shown in FIG. 2b. As illustrated, at a depth 0, which may thus correspond to an interface between the silicon dioxide layer 211 and the material 252, a maximum germanium concentration may be obtained, which may have a value of approximately 34 percent, while the corresponding silicon concentration may thus be 64 percent. With increasing depth, the germanium concentration may drop, while still a moderately high concentration at a thickness of approximately 45 nm may be present, which may substantially correspond to the germanium concentration of the material 252 as initially provided on the basis of the selective epitaxial growth process. Therefore, as indicated, a significant germanium concentration may still be present at an increased depth and may finally drop at the interface 202S so that at least down to the interface 202S a significant amount of germanium species is present. Consequently, the significantly increased overall germanium contents and the increased lateral and vertical extension of the material 252 may provide a significantly higher compressive strain in the channel region 251 (FIG. 2b). It should also be appreciated that the lateral growth of the material 252 may provide superior strain conditions in the channel region 251, even if the spacer structure 255D (FIG. 2b) may be provided with an appropriate width so as to obtain superior integrity of the gate electrode structure 255. That is, a germanium concentration, which may be comparable to a germanium concentration as obtained by selective epitaxial growth techniques, may be obtained with reduced lateral offset with respect to the channel region 251, even if a less critical process technique may be applied in order to form the cavities 204 (FIG. 2a), thereby reducing the probability of creating process-related non-uniformities and device variations, which may be caused by damage of sensitive gate materials, as is also explained above.

FIG. 2d schematically illustrates the situation for a device in which, for instance, process parameters of the process 210 may be selected so as to further increase the maximum germanium concentration and thus the overall germanium contents in the material 252. As illustrated, at a depth 0, a maximum concentration may be approximately 55 percent, while the corresponding silicon concentration may thus be about 45 percent. The germanium concentration may slowly decrease and may still have a very high value at the interface 202S of, for instance, approximately 41 percent. To this end, for example, the process time may be appropriately selected when starting from substantially similar material conditions as described with reference to FIG. 2c. Hence, a moderately high concentration may be obtained across the entire depth of the active region, thereby even further increasing the resulting compressive strain. It should be appreciated that even a maximum concentration of approximately 100 percent germanium may be achieved on the basis of the condensation process 210 as described with reference to FIG. 2b. To this end, appropriate material characteristics and process parameters may be selected, wherein the corresponding parameter settings may be readily determined on the basis of experiments, as already discussed above.

FIG. 2e schematically illustrates the semiconductor device 200 according to further illustrative embodiments. As shown, the base material 203B in the active region 203A may be provided in a non-recessed configuration, and a sacrificial material 205 in the form of a silicon/germanium mixture is formed on the base material 203B. The semiconductor device 200 as illustrated in FIG. 2e may be formed on the basis of process techniques as previously described when referring to a gate patterning process. It should be appreciated, however, that, in the embodiment shown in FIG. 2e, the spacer structure 255D may be appropriately adjusted so as to take into consideration a lateral diffusion of a germanium species of the sacrificial layer 205 during the germanium condensation process 210. That is, since, in some illustrative embodiments, an increased germanium diffusion may be considered appropriate for the device 200, the width of the spacer structure 255D may be accordingly increased when the lateral extension of the resulting germanium concentration is to be restricted. In other cases, an increased lateral diffusion of the germanium species may be considered appropriate and the structure 255D may thus be provided with a similar width, as previously discussed with reference to FIGS. 2a and 2b. Consequently, during the process 210, silicon material is increasingly consumed and is converted into a silicon dioxide material, while the germanium species in the layer 205 is driven into the lower lying base material 203B, thereby increasingly forming a silicon/germanium alloy whose germanium concentration increases during the advance of the process 210.

FIG. 2f schematically illustrates the device 200 in a final stage of the germanium condensation process 210. As shown, the sacrificial material 205 of FIG. 2e is substantially completely converted into a silicon dioxide material, as indicated by 212, while, on the other hand, a silicon/germanium material 252 is formed in the base material 203B due to the germanium diffusion, as explained above. In the example shown, the initial thickness of the sacrificial material 205 of FIG. 2e, as well as the process parameters of the process 210, have been selected such that a substantially planar surface configuration is preserved for the active region 203A. In other cases, the corresponding parameters may be readily selected so as to obtain a recessed or raised configuration, as is also discussed earlier. Furthermore, as indicated, the strain-inducing semiconductor material 252 may have a lateral extension, as indicated by 252L, which may substantially correspond to a depth 252D, wherein a desired lateral offset from the channel region 251 may thus be adjusted on the basis of the width of the spacer structure 255D, as discussed above. Consequently, the strain-inducing material 252 may be obtained with a size and shape as may be controlled on the basis of the process parameters of the process 210 and the material composition of the initial sacrificial material 205 (FIG. 2e), while avoiding the complex patterning process for forming cavities in the active region 203A.

FIG. 2g schematically illustrates the semiconductor device 200 in a further advanced manufacturing stage. As shown, drain and source regions 253 may be provided within the active region 203A and thus at least within a portion of the germanium-containing strain-inducing material 252. Furthermore, any appropriate spacer structure 255S may be provided in the gate electrode structure 255, as required for obtaining the desired lateral and vertical profile of the drain and source regions 253. The device 200 as shown in FIG. 2g may be formed on the basis of any appropriate process strategy, wherein, starting from the device configuration as, for instance, shown in FIG. 2b or 2f, the silicon oxide-based materials 211 or 212 may be removed by any appropriate etch process, for instance by wet chemical etch recipes, followed by process techniques for forming the spacer structure 255S in combination with incorporating any dopant species as required for profiling the drain and source regions 253. Thereafter, any anneal processes may be applied in order to adjust the final dopant profile. Thereafter, metal silicide regions may be provided, if required, while, in other cases, an appropriate interlayer dielectric material may be formed, which may then in turn be patterned so as to form openings therein, which may be filled with any conductive material so as to electrically connect to the gate electrode structure 255 and/or to the drain and source regions 253. If required, replacement gate approaches may be applied in which a portion of the gate materials may be removed and may be replaced with sophisticated material or material systems, such as high-k dielectric materials, highly conductive gate metals and the like.

As a result, the present disclosure provides semiconductor devices and manufacturing techniques in which high germanium concentrations may be obtained without generating undue lattice irregularities by using a germanium condensation technique, wherein the initial device configuration and/or the process parameter may be selected so as to obtain the desired germanium concentration and profile. For example, a maximum germanium concentration of 30 atomic percent and higher may be achieved without undue lattice effects, wherein a high germanium concentration may extend down to a buried insulating material of an SOI architecture. In some illustrative embodiments, even a maximum germanium concentration of 100 percent may be obtained by appropriately selecting the process parameters of the condensation process. It should be appreciated that implementing the germanium condensation process in the form of an oxidation process has been described above, while, in other illustrative embodiments, other processes, such as nitridation and the like, may also be applied, as long as a reduced chemical activation energy of silicon may result in a preferred conversion of silicon into a silicon compound, which in turn may drive the germanium species into the lower lying device areas. On the other hand, the silicon compound may then be efficiently removed, for instance in the form of a silicon dioxide material, a silicon nitride material, a silicon oxynitride material and the like, without unduly affecting the underlying strain-inducing semiconductor material comprising the increased germanium concentration.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a semiconductor material on a silicon-containing semiconductor base material of a semiconductor region having formed thereon a gate electrode structure, said semiconductor material comprising germanium;
oxidizing at least a portion of said semiconductor material so as to drive germanium species into said silicon-containing semiconductor base material;
removing an oxidized portion of said semiconductor material; and
forming drain and source regions in said semiconductor region.

2. The method of claim 1, wherein forming said semiconductor material comprises forming cavities in said semiconductor region laterally adjacent to said gate electrode structure and forming said semiconductor material at least in said cavities.

3. The method of claim 2, wherein said semiconductor material is formed at least in said cavities so as to overfill said cavities.

4. The method of claim 1, wherein said semiconductor material has an initial maximum germanium concentration of approximately 30 atomic percent or less.

5. The method of claim 1, wherein said semiconductor material is formed on said silicon-containing semiconductor base material without forming a cavity in said semiconductor region.

6. The method of claim 1, further comprising providing a buried insulating layer below said semiconductor region.

7. The method of claim 1, wherein oxidizing at least a portion of said semiconductor material comprises establishing a substantially pure oxygen atmosphere at a substrate temperature of approximately 900° C. or higher.

8. The method of claim 7, wherein a process time in said substantially pure oxygen atmosphere is approximately 40 minutes or greater.

9. The method of claim 1, wherein forming said semiconductor material comprises forming said semiconductor material with an initial thickness of approximately 150 nm or less.

10. A method of forming a transistor, the method comprising:
forming a silicon/germanium alloy on a silicon-containing semiconductor base material of an active region of said transistor;
annealing said silicon/germanium alloy so as to convert silicon into a silicon compound in at least a portion of said silicon/germanium alloy and to increase a germanium concentration outside of said silicon compound;
removing said silicon compound; and
forming drain and source regions in said active region, said drain and source regions having a strained state caused by said increased germanium concentration.

11. The method of claim 10, wherein annealing said silicon/germanium alloy comprises establishing an oxidizing ambient.

12. The method of claim 10, wherein said silicon/germanium alloy is annealed for approximately 40 minutes or more at a temperature of approximately 900° C. or higher.

13. The method of 10, wherein forming a silicon/germanium alloy on a silicon-containing semiconductor base material comprises forming a cavity in said active region and filling said cavity with said silicon/germanium alloy.

14. The method of claim 10, wherein forming said silicon/germanium alloy comprises varying a germanium concentration in a deposition ambient.

15. The method of claim 10, wherein forming said silicon/germanium alloy comprises adjusting a maximum germanium concentration to approximately 30 atomic percent or less.

16. The method of claim 10, wherein said drain and source regions are formed so as to have a P-type conductivity.

17. The method of claim 10, further comprising forming a gate electrode structure on said active region prior to forming said silicon/germanium alloy.

18. A semiconductor device, comprising:
a gate electrode structure of a transistor formed above an active region;
a silicon-containing channel region formed in said active region under a portion of said gate electrode structure;
a strained semiconductor material formed in said active region and inducing a compressive strain in said channel region, said strained semiconductor material comprising germanium with a maximum concentration of 30 atomic percent or higher;
drain and source regions formed in said active region; and
a buried insulating layer formed below said active region and forming an interface therewith, said strained semiconductor material comprising germanium extending to said interface in said drain and source regions.

19. The semiconductor device of claim 18, wherein said maximum germanium concentration is approximately 40 atomic percent or higher.

20. The semiconductor device of claim 18, wherein a thickness of said active region below said gate electrode structure is approximately 100 nm or less.
